(19) United States
(12) Patent Application Publication
(10) Pub. No.: US 2025/0294717 A1
(43) Pub. Date: Sep. 18, 2025

(54) MEMORY STRUCTURE

(71) Applicant: MACRONIX INTERNATIONAL CO., LTD., Hsinchu (TW)

(72) Inventors: Wei-Chen CHEN, Taoyuan County (TW); Hang-Ting LUE, Zhubei City (TW)

(21) Appl. No.: 18/603,264

(22) Filed: Mar. 13, 2024

(51) Int. Cl. H10B 12/00

(52) U.S. Cl. CPC H10B 12/20

(57) ABSTRACT

A memory structure includes a substrate having an upper surface; a first gate structure and a second gate structure disposed on the substrate, separated from each other in a first direction and extend in a second direction, respectively; and a plurality of channel bodies separated from each other in the first direction and a third direction, and penetrating the first gate structure and the second structure, respectively. The first direction, the second direction and the third direction intersect each other. The upper surface is parallel to the first direction and the second direction, and a normal direction of the upper surface is parallel to the third direction. A first length of the first gate structure in the first direction and a second length of the second gate structure in the first direction are different from each other.

### BACKGROUND OF THE INVENTION

### Field of the Invention

The invention relates in general to a semiconductor structure, and more particularly to a memory structure.

### Description of the Related Art

Recently, in order to cope with market demand, the size of memory structures needs to be smaller and smaller. Various types of three-dimensional memory structures are developing rapidly. However, the current three-dimensional memory structure still needs further improvement to reduce the size of the memory structure while still maintaining the performance of the memory structure.

### SUMMARY OF THE INVENTION

The present invention relates to a memory structure based on a thyristor-based operating mechanism, which has the advantages of high scalability and fast operating speed.

According to an embodiment of the present invention, a memory structure is provided. The memory structure includes a substrate having an upper surface; a first gate structure and a second gate structure disposed on the substrate, separated from each other in a first direction and extend in a second direction, respectively; and a plurality of channel bodies separated from each other in the first direction and a third direction, and penetrating the first gate structure and the second structure, respectively. The first direction, the second direction and the third direction intersect each other. The upper surface is parallel to the first direction and the second direction, and a normal direction of the upper surface is parallel to the third direction. A first length of the first gate structure in the first direction and a second length of the second gate structure in the first direction are different from each other.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A is a schematic three-dimensional view of a memory structure according to an embodiment of the present invention.

FIG. 1B is a schematic three-dimensional view of a memory structure according to another embodiment of the present invention.

FIG. 2 is a schematic three-dimensional view of a memory structure according to yet another embodiment of the present invention.

FIG. 3 is a schematic three-dimensional view of a memory structure according to a further embodiment of the present invention.

FIG. 4A is a partial top view of a memory structure according to Embodiment A1 of the present invention.

FIG. 4B is a partial cross-sectional view of the memory structure of FIG. 4A.

FIG. 5A is a partial top view of a memory structure according to Comparative example A1.

FIG. 5B is a partial cross-sectional view of the memory structure of FIG. 5A.

FIGS. 6A and 6B are schematic diagrams showing current-voltage relationship curves of memory cell units of Embodiment A1 and Comparative Example A1 when different voltages are applied, respectively.

FIGS. 7A and 7B are diagrams showing time-bias waveform of the first gate structure, the second gate structure and the bit line of one of the memory cell units according to the memory structure of Embodiment A1 in different operating states.

FIG. 7C is a diagram showing current-retention time relationship of Embodiment A1 and Comparative Example A1.

FIG. 8A is a diagram showing bit line current-bit line voltage relationship curves of the memory cell units of Embodiments A1 to A4.

FIG. 8B is a diagram showing bit line current-bit line voltage relationship curves of the memory cell units of Embodiments A1 and B2 to B4.

FIG. 9A shows a partial cross-sectional view of the memory structure of Embodiment A4.

FIG. 9B is a schematic diagram showing bit line current-bit line voltage relationship curves of one of the memory cell units in the memory structure of Embodiment A4.

FIG. 9C shows the changes in bias and current over time in different operating states of Embodiment A4.

FIG. 10 shows an equivalent circuit diagram of a memory structure according to an embodiment of the present invention.

FIG. 11 shows the simulation results of the read operation of the memory cell unit CC.

FIG. 12A shows the simulation results of the programming operation of the memory cell unit CC at the “0” state.

FIG. 12B shows the simulation results of the programming operation of the memory cell unit CC at the “1” state.

FIG. 12C shows the simulation results of the programming operation of the memory cell unit CD at the “0” state.

FIG. 12D shows the simulation results of the programming operation of the memory cell unit CD at the “1” state.

FIG. 13A shows the simulation results of the erase operation of the memory cell unit CC at the “0” state.

FIG. 13B shows the simulation results of the erase operation of the memory cell unit CC at the “1” state.

FIG. 13C shows the simulation results of the erase operation of the memory cell unit CD at the “0” state.

FIG. 13D shows the simulation results of the erase operation of the memory cell unit CD at the “1” state.

### DETAILED DESCRIPTION OF THE INVENTION

The following are related embodiments, together with the drawings, to describe the memory structure provided by the present invention in detail. However, the present invention is not limited thereto. The descriptions in the embodiments, such as the detailed structure, the operating method, and the material application, etc., are only for the purpose of illustration, and the scope of protection of the present invention is not limited to the mentioned implementation aspects.

At the same time, it should be noted that this disclosure does not show all possible embodiments. One of ordinary skilled in the art can make changes and modifications to the structures and operating methods of the embodiments to meet the needs of practical applications without departing from the spirit and scope of the present disclosure. Therefore, other implementation aspects not proposed in the present disclosure may also be applicable. Furthermore, the drawings are simplified for the purpose of clearly explaining the contents of the embodiments, and the dimension and ratios in the drawings are not drawn according to the actual product scale. Therefore, the description and the drawings are only used to describe the embodiments, rather than to limit the protection scope of the present disclosure. The same or similar reference numerals are used to represent the same or similar elements.

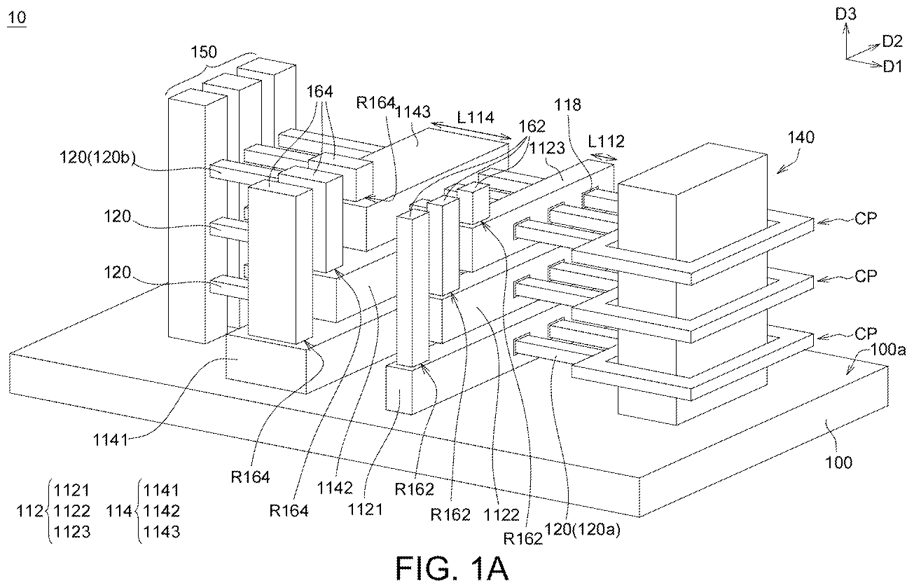

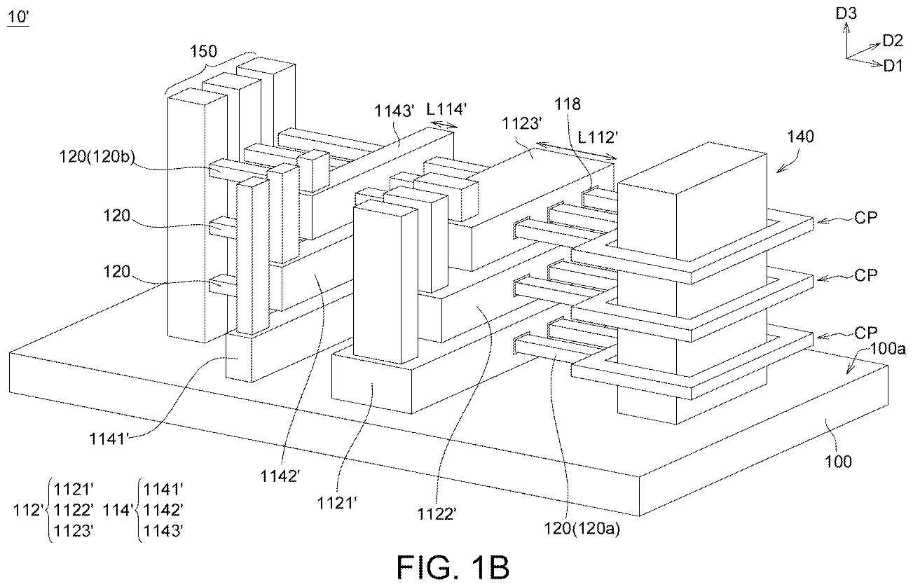

Referring to FIG. 1A, it is a schematic three-dimensional view of a memory structure 10 according to an embodiment of the present invention. The memory structure 10 includes a substrate 100, a first gate structure 112 and a second gate structure 114, a plurality of channel bodies 120, a plurality of pads CP, a first side plug 140, a plurality of second side plugs 150, a plurality of contacts (for example, a plurality of first contacts 162 and a plurality of second contacts 164) and a plurality of dielectric films 118. In order to make the diagram more concise, some insulating materials are omitted in FIG. 1A. For example, the insulating materials between the substrate 100, the channel bodies 120, the first gate structure 112 and the second gate structure 114 are omitted.

As shown in FIG. 1A, the substrate 100 has an upper surface 100a. The first gate structure 112 and the second gate structure 114 are disposed on the substrate 100 and are separated from each other in the first direction D1 and extend along the second direction D2, respectively. For example, lengths of the first gate structure 112 and the second gate structure 114 in the second direction D2 is greater than lengths of the first gate structure 112 and the second gate structure 114 in the first direction D1. In other words, the memory structure 10 of the present embodiment includes two gate structures, i.e. the first gate structure 112 and the second gate structure 114. The bias applied by the first gate structure 112 and the second gate structure 114 A bias is used to control the operation of the memory structure 10. The channel bodies 120 are separated from each other in the second direction D2 and the third direction D3 and respectively extend along the first direction D1 and penetrate the first gate structure 112 and the second gate structure 114. As shown in FIG. 1A, the first direction D1, the second direction D2 and the third direction D3 intersect with each other, the upper surface 100a of the substrate 100 is parallel to the first direction D1 and the second direction D2, and a normal direction of the upper surface 100a is parallel to the third direction D3. The first direction D1, the second direction D2 and the third direction D3 are substantially perpendicular to each other. The channel bodies 120 may be orthogonal to the first gate structure 112 and the second gate structure 114.

In FIG. 1A, the first gate structure 112 and the second gate structure 114 have asymmetric lengths, that is, a first length L112 of the first gate structure 112 in the first direction D1 and a second length L114 of the second gate structure 114 in the first direction D1 are different from each other. For example, the first length L112 is smaller than the second length L114, but the present invention is not limited thereto. In the present embodiment, the first gate structure 112 includes a plurality of portions 1121-1123, and the lengths of the portions 1121-1123 in the first direction D1 are the same as each other (i.e. first length L112); the second gate structure 114 includes a plurality of portions 1141-1143, and the lengths of the portions 1141-1143 in the first direction D1 are the same as each other (i.e. second length L114). Each of portions 1121-1123 of the first gate structure 112 extends along the second direction D2, and the portions 1121-1123 are separated from each other along the third direction D3, for example, by an insulating material (not shown), and are not in direct contact. The lengths of the portions 1121-1123 in the second direction D2 are different from each other. For example, the lengths of the portions 1121-1123 in the second direction D2 decrease along the second direction D2. That is, the length of the portion 1121 in the second direction D2 is greater than the length of the portion 1122 in the second direction D2, the length of the portion 1122 in the second direction D2 is greater than the length of the portion 1123 in the second direction D2. Each of portions 1141-1143 of the second gate structure 114 extends along the second direction D2, and the portions 1141-1143 are separated from each other along the third direction D3, for example, by an insulating material (not shown), and are not in direct contact. Similarly, the lengths of the portions 1141-1143 in the second direction D2 are different from each other. For example, the lengths of the portions 1141-1143 in the second direction D2 decrease along the second direction D2, that is, the length of the portion 1141 in the second direction D2 is greater than the length of the portion 1142 in the second direction D2, and the length of the portion 1142 in the second direction D2 is greater than the length of the portion 1143 in the second direction D2.

As shown in FIG. 1A, the pads CP are stacked along the third direction D3 and separated from each other along the third direction D3. Each of pads CP is connected to a corresponding first end 120a in the channel body 120, for example, each of the three pads CP are connected to the three first ends 120a of the three channel bodies 120 that overlap each other in the second direction D2. The first side plug 140 extends along the third direction D3 and connects all the pads CP. The second side plugs 150 respectively extend along the third direction D3 and are separated from each other in the second direction D2. Each of second plugs 150 is connected to a corresponding second end 120b in the channel body 120, for example, each of second side plugs 150 is connected to the three second ends 120b of the three channel bodies 120 that overlap each other in the third direction D3. The second end 120b is opposite to the first end 120a, that is, the first end 120a and the second end 120b are two opposite ends of the channel body 120 extending in the first direction D1. The first gate structure 112 is closer to the first end 120a than the second gate structure 114, and the second gate structure 114 is closer to the second end 120b than the first gate structure 112. According to an embodiment, the first end 120a includes a first conductive type dopant, the second end 120b includes a second conductive type dopant, and the second conductive type dopant is different from the first conductive type dopant. For example, the first conductive type dopant is an N-type dopant, and the first conductive type dopant is a P-type dopant, that is, the first end 120a includes a high concentration of N-type dopant (N+), and the second end 120b includes a high concentration of P-type dopants (P+).

As shown in FIG. 1A, dielectric films 118 are disposed between the first gate structure 112 and the channel bodies 120 and between the second gate structure 114 and the channel bodies 120. Each of portions 1121-1123 of the first gate structure 112 can surround multiple channel bodies 120 and dielectric films 118, for example, three channel bodies 120 and dielectric films 118 at the same level. The portions 1121-1123 form three gate-all-around (GAA) structures. Each of portions 1141-1143 of the second gate structure 114 can surround multiple channel bodies 120 and dielectric films 118, for example, three channel bodies 120 and dielectric films 118 at the same level. The portions 1141-1143 form three gate-all-around (GAA) structures.

In FIG. 1A, the first contacts 162 are separated from each other along the second direction D2, and respectively extend along the third direction D3 to electrically contact a plurality of first landing regions R162 on the portions 1121-1123 of the first gate structure 112. The heights of the first contacts 162 in the third direction D3 are different from each other, for example, forming stepped contacts, and the first landing regions R162 forms a staircase structure. The second contacts 164 are separated from each other along the second direction D2 and respectively extend along the third direction D3 to electrically contact a plurality of second landing regions R164 on the portions 1141-1143 of the second gate structure 114. The heights of the second contacts 164 in the third direction D3 are different from each other, for example, forming stepped contacts, and the second landing regions R164 form another staircase structure. Since the portions 1121-1123 of the first gate structure 112 and the portions 1141-1143 of the second gate structure 114 can respectively control the bias through the stepped first contacts 162 and second contacts 164, word line bias in different layers (pages) can be adjusted independently, so page erase can be performed, and the disturb and retention of unselected pages can be adjusted more easily (detailed below).

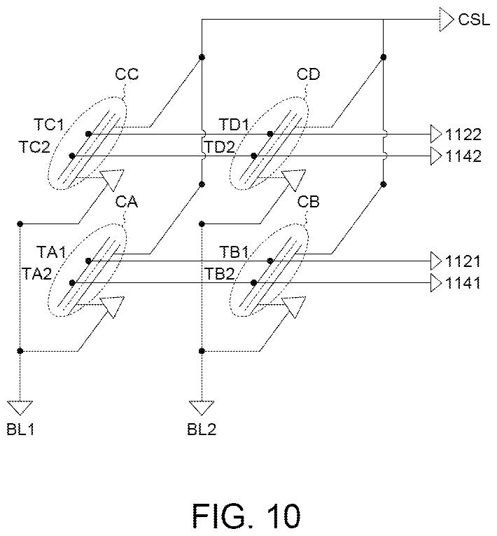

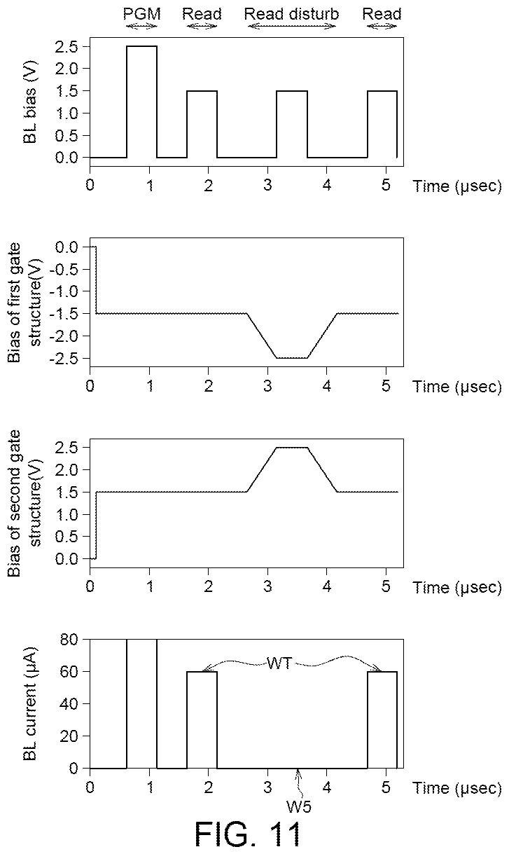

According to an embodiment, the memory structure 10 further includes a plurality of memory units (such as memory units CA-CD as shown in FIG. 10), and each of memory units (such as memory units CA-CD) is formed of the corresponding one of channel bodies 120, the first gate structure 112 and the second gate structure 114, as shown in the equivalent circuit diagram of FIG. 10.

Please refer back to FIG. 1A. According to the present embodiment, the first gate structure 112 and the second gate structure 114 can respectively serve as a plurality of word lines (WL). For example, each of portions 1121-1123 of the first gate structure 112 can be used as a word line, that is, the first gate structure 112 can correspond to three word lines; each of portions 1141-1143 of the second gate structure 114 can be used as a word line, that is, the second gate structure 114 can correspond to three word lines. The first side plug 140 may serve as a common source line (CSL). Each of second side plug 150 may serve as a bit line (BL).

In some embodiments, the substrate 100 may include a semiconductor substrate, such as a bulk silicon substrate. In the present embodiment, the channel bodies 120 may be formed by a selective epitaxial growth process, and the material of the channel bodies 120 may include single crystal silicon. The channel bodies 120 may be used to store carriers (e.g., electrons or holes) during operations (e.g., programming or erasing) of the memory structure 10. The dielectric films 118 do not need to have the function of storing carriers (such as electrons or holes), so the dielectric films 118 do not include a charge storage structure, such as an oxide-nitride-oxide (ONO) structure. In one embodiment, the material of the dielectric films 118 includes a dielectric material, such as an oxide, and the dielectric film 118 may be a single-layer structure. In one embodiment, the material of the dielectric films 118 may include a high-k material. In one embodiment, materials of the first contacts 162, the second contacts 164, the first side plug 140, the second side plug 150, the first gate structure 112 and the second gate structure 114 may include semiconductor materials or metallic material. It should be understood that the materials of the above-mentioned elements of the present invention are not limited thereto.

Compared with the embodiment in which the first gate structure and the second gate structure have the same length in the first direction D1 (for example, both are 90 nm), the first gate structure 112 of the present embodiment has the first length L112 in the first direction D1 which is less than the second length L114 of the second gate structure 114 in the first direction D1 (for example, the first length L112=30 nm, the second length L114=90 nm), that is, the first gate structure 112 can occupy a smaller volume, so the size of the memory structure can be reduced to meet the requirements of miniaturization.

FIG. 1B is a schematic three-dimensional view of a memory structure 10′ according to another embodiment of the present invention. One of the main differences between the memory structure 10′ and the memory structure 10 is that the first length L112′ and the second length L114′ are different, and other identical parts will not be described in detail.

Please refer to FIG. 1B. The first gate structure 112′ (including portions 1121′-1123′) and the second gate structure 114′ (including portions 1141′-1143′) have asymmetric lengths, that is, a first length L112′ of the first gate structure 112′ in the first direction D1 and a second length L114′ of the second gate structure 114′ in the first direction D1 are different from each other. For example, the second length L114′ is smaller than the first length L112′, but the invention is not limited thereto.

Compared with the embodiment in which the first gate structure and the second gate structure have the same length in the first direction D1 (for example, both are 90 nm), in the present embodiment, the second length L114′ of the second gate structure 114′ in the first direction D1 is less than the first length L112′ of the first gate structure 112′ in the first direction D1 (for example, the first length L112′=90 nm, the second length L114′=30 nm), that is, the second gate structure 114′ can occupy a smaller volume, so the size of the memory structure can be reduced to meet the requirements of miniaturization.

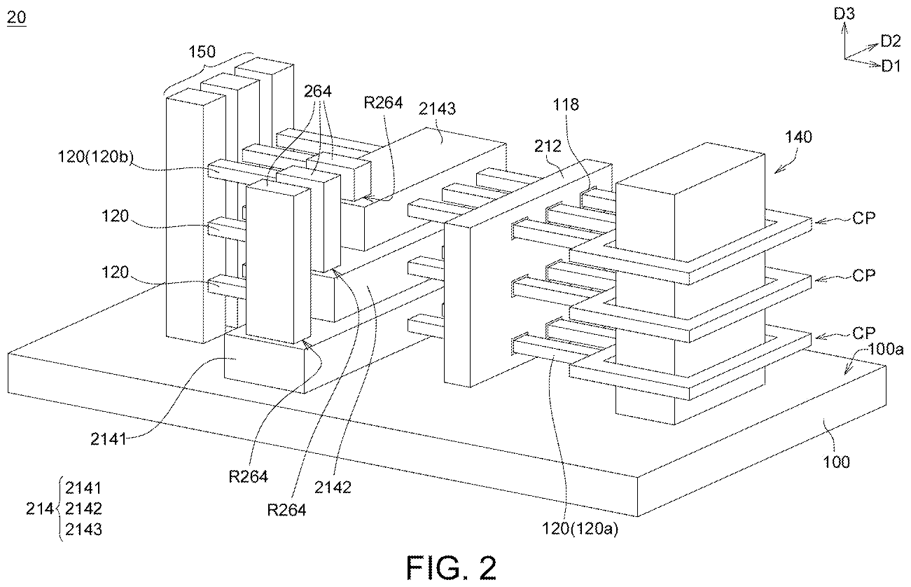

FIG. 2 is a schematic three-dimensional view of a memory structure 20 according to yet another embodiment of the present invention. One of the main differences between the memory structure 20 and the memory structure 10 is that the first gate structure 212 is different from the first gate structure 112, and other identical parts will not be described in detail.

Referring to FIG. 2. The first gate structure 212 is a continuous structure in the third direction D3 and does not have a plurality of portions separated from each other. Similar to the second gate structure 114, the second gate structure 214 includes a plurality of portions 2141-2143. The portions 2141-2143 of the second gate structure 214 respectively extend along the second direction D2, and are separated from each other along the third direction D3. The first gate structure 212 corresponds to all channel bodies 120, for example, the first gate structure 212 surrounds all channel bodies 120. Similar to the second gate structure 114, the portions 2141-2143 of the second gate structure 214 respectively correspond to a portion of the channel bodies 120. For example, each of portions 2141-2143 surrounds three channel bodies 120 overlapping in the second direction D2. Similar to the second contacts 164, the contacts 264 are separated from each other along the second direction D2 and respectively extend along the third direction D3 to electrically contact a plurality of landing regions R264 on the portions 2141-2143 of the second gate structure 214, and the landing regions R264 form a staircase structure.

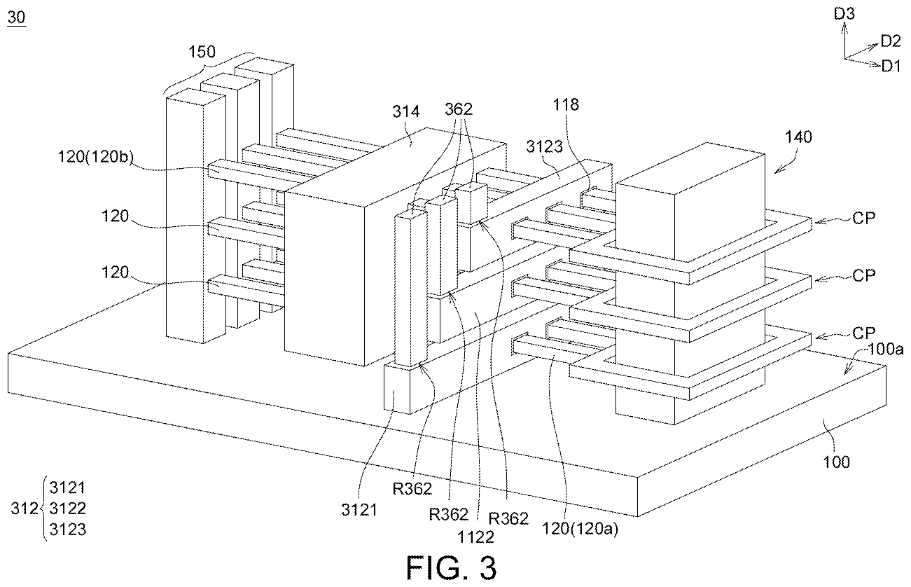

FIG. 3 is a schematic three-dimensional view of a memory structure 30 according to a further embodiment of the present invention. One of the main differences between the memory structure 30 and the memory structure 10 is that the second gate structure 314 is different from the second gate structure 114, and other identical parts will not be described in detail.

Referring to FIG. 3, the second gate structure 314 is a continuous structure in the third direction D3 and does not have a plurality of portions separated from each other. Similar to the first gate structure 112, the first gate structure 312 includes a plurality of portions 3121-3123. The portions 3121-3123 of the first gate structure 312 respectively extend along the second direction D2 and are separated from each other along the third direction D3. The second gate structure 314 corresponds to all channel bodies 120, for example, the second gate structure 314 surrounds all channel bodies 120. Similar to the first gate structure 112, the portions 3121-3123 of the first gate structure 312 respectively correspond to a portion of the channel bodies 120. For example, each of portions 3121-3123 surrounds three channel bodies 120 overlapping each other in the second direction D2. Similar to the first contacts 162, the contacts 362 are separated from each other along the second direction D2 and respectively extend along the third direction D3 to electrically contact a plurality of landing regions R362 on the portions 3121˜3123 of the first gate structure 312, and the landing regions R362 form a staircase structure.

In FIGS. 1A-3, the memory structures 10-30 of the present invention include a plurality of memory cell units, and each of memory cell units is a thyristor. More specifically, the memory cell units of the memory structure 10˜30 control the operation of the thyristor through the gate, so the memory cell unit is also called a gate-controlled-thyristor (GCT). Based on the characteristics of the gate-controlled-thyristor, the access speed of the memory structure 10˜30 can reach the level of random access memory (RAM). That is, the operating mechanisms of the memory structures 10 to 30 of the present invention are all based on thyristors. It should be understood that the memory structure of the present invention is not limited to the embodiments shown in FIGS. 1A-3.

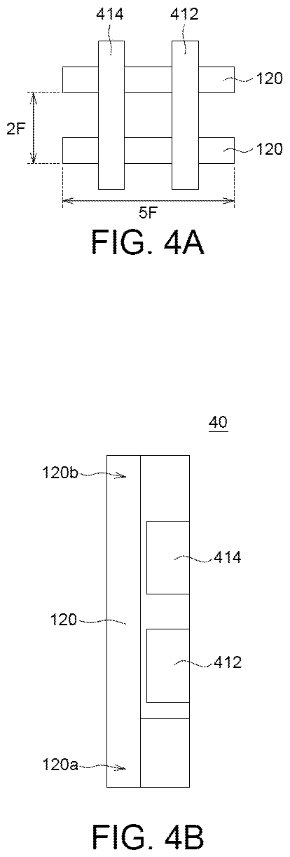

FIG. 4A is a partial top view of a memory structure 40 according to Embodiment A1 of the present invention. FIG. 4B is a partial cross-sectional view of the memory structure 40 of FIG. 4A. One of the main differences between the memory structure 40 and the memory structure 10 is that the first gate structure 412 and the second gate structure 414 are symmetrical to each other, and other identical parts will not be described in detail. In order to make the drawings more concise, the insulating material and the dielectric films are omitted in FIGS. 4A and 4B.

Referring to FIGS. 4A and 4B at the same time, the first gate structure 412 and the second gate structure 414 have symmetrical lengths, that is, the length of the first gate structure 412 in the first direction D1 is equal to the length of the second gate structure 414 in the first direction D1 (for example, both are equal to 90 nm).

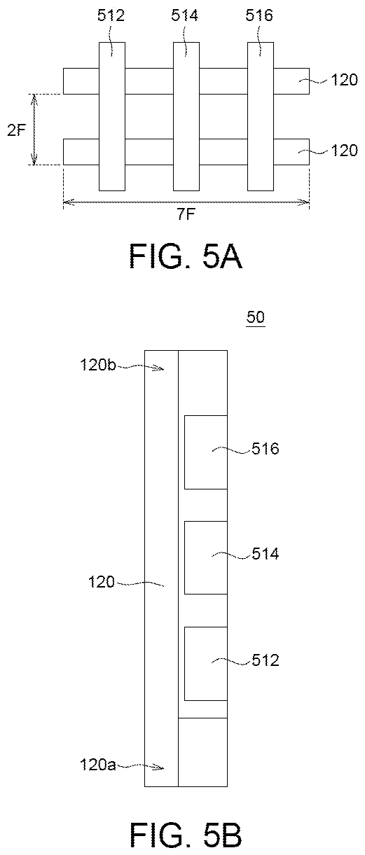

FIG. 5A is a partial top view of a memory structure 50 according to Comparative example A1. FIG. 5B is a partial cross-sectional view of the memory structure 50 of FIG. 5A. One of the main differences between the memory structure 50 and the memory structure 40 is that the memory structure 50 further includes a third gate structure 516, and the first gate structure 512, the second gate structure 514 and the third gate structure 516 respectively surround all of the channel bodies 120, and other identical parts will not be described in detail.

As shown in FIGS. 4A and 5A, the lengths (for example, 90 nm) and the spacing (for example, 25 nm) of the first gate structure 412 and the second gate structure 414 of the memory structure 40 and the first gate structure 512, the second gate structure 514 and the third gate structure 516 of the memory structure 50 in the first direction D1 are the same. A size per unit area of memory cell in the memory structure 40 may be 10F², and a size per unit area of memory cell in the memory structure 50 may be 14F², wherein F represents a feature size, for example, a minimum value of half pitch of memory cell. It can be seen that the memory structure 40 of the two-gate structure has a smaller size in unit area than the memory structure 50 of the three-gate structure, and is more in line with the demand for miniaturization of the memory structure.

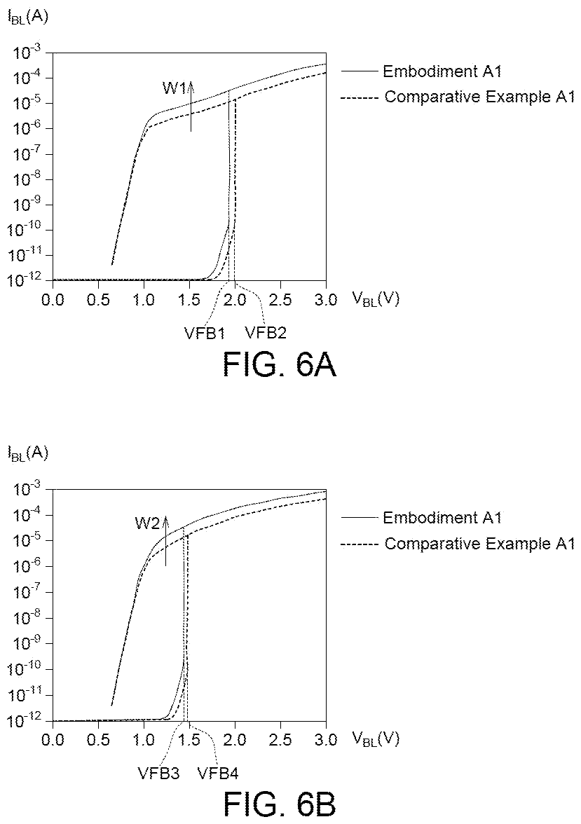

FIGS. 6A and 6B are schematic diagrams showing current-voltage relationship curves of memory cell units of Embodiment A1 (as shown in FIGS. 4A and 4B) and Comparative Example A1 (as shown in FIGS. 5A and 5B) when different voltages are applied, respectively. For example, in FIG. 6A, −1.5V is applied to the first gate structure 412 of the memory structure 40, and 1.5V is applied to the second gate structure 414 of the memory structure 40; −1.5V is applied to the first gate structure 512 of the memory structure 50, 1.5V is applied to the second gate structure 514 of the memory structure 50, and 1.5V is applied to the third gate structure 516 of the memory structure 50. In FIG. 6B, −1V is applied to the first gate structure 412 of the memory structure 40, and 1V is applied to the second gate structure 414 of the memory structure 40; −1V is applied to the first gate structure 512 of the memory structure 50, 1V is applied to the second gate structure 514 of the memory structure 50 and 1V applied to the third gate structure 516 of the memory structure 50. In FIGS. 6A and 6B, the X-axis represents the bit line bias (VBL) in volts (V); the Y-axis represents the bit line current (IBL) in amperes (A). The solid curve represents forward bias (for example, scanning from the left to the right), and the dotted curve represents the reverse bias (for example, scanning from the right to the left).

The operating mechanisms of Embodiment A1 and Comparative Example A1 are both based on thyristors, and the current-voltage curve of the memory cell unit is highly nonlinear, also known as a hysteresis curve. When the memory cell unit performs a programming operation (i.e., write operation) to write a logic value “1”, the memory cell unit is in a programming state (“1”). When the memory cell unit performs an erase operation to erase the logic value to “0”, the memory cell unit is in an erase state (“0”). The drain-source voltage difference of a memory cell unit is the voltage difference between the bit line voltage and the source line voltage. When the voltage difference between the drain and the source is less than the inherent built-in potential barrier of the PN junction of the memory cell unit, the memory cell unit is in the erase state (“0”) and the memory cell unit stores the logic value “0”. On the other hand, when the voltage difference between the drain and the source is greater than the forward breakdown voltage of the forward bias (such as VFB1 or VFB2 as shown in FIG. 6A), the voltage difference between the drain and the source is in the interval of programming bias, a positive feedback of the memory cell unit can be triggered to perform write operations. In addition, when the voltage difference between the drain and the source of the memory cell unit is between the inherent built-in potential barrier of the PN junction and the forward breakdown voltage (such as VFB1 or VFB2 as shown in FIGS. 6A), the drain-source voltage difference is in the interval of read bias. In the interval of read bias, the on-off current ratio of the memory cell unit has a large value. More specifically, the on-off current ratio is defined as the ratio of the current value of the bit line in the programming state (“1”) to the current value of the bit line in the erase state (“0”). Since the value of the on-off current ratio is very large, within the interval of read bias, it can be clearly distinguished whether the memory cell unit is in the programming state (“1”), which stores the logic value “1”, or is in the erase state (“0”), which stores the logical value “0”.

Referring to FIG. 6A, the breakdown voltage VFB1 of Embodiment A1 is not much different from the breakdown voltage VFB2 of Comparative Example A1, and the on-current of Embodiment A1 shows a significant increase compared with the on-current of Comparative Example A1, as indicated by arrow W1. Similarly, referring to FIG. 6B, the breakdown voltage VFB3 of Embodiment A1 is not much different from the breakdown voltage VFB4 of Comparative Example A1, while the on-current of Embodiment A1 is significantly increased compared to the conduction current of Comparative Example A1. As shown by arrow W2.

It can be seen that compared with the memory structure 50 having the three-gate structure, the memory structure 40 having the two-gate structure will not cause the breakdown voltage (such as VFB1 and VFB3) to drop too much, and the on-current can also be increased, which provides a larger current interval, making the window between the programming state (“1”) and the erase state (“0”) larger.

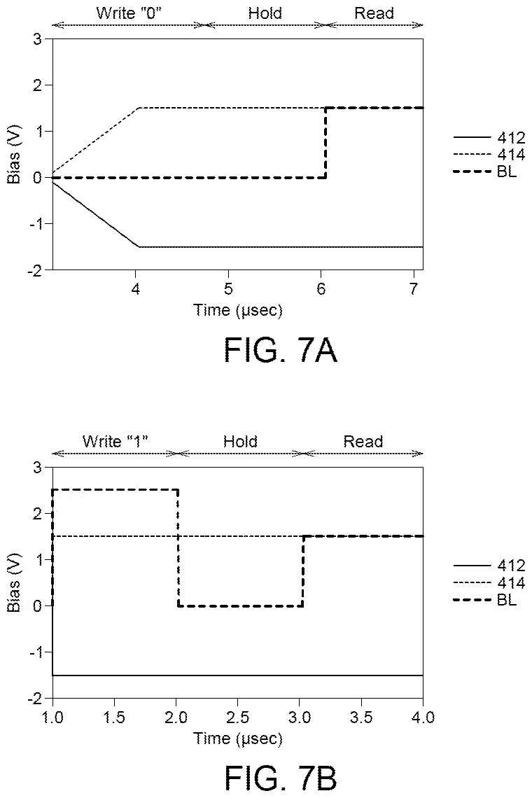

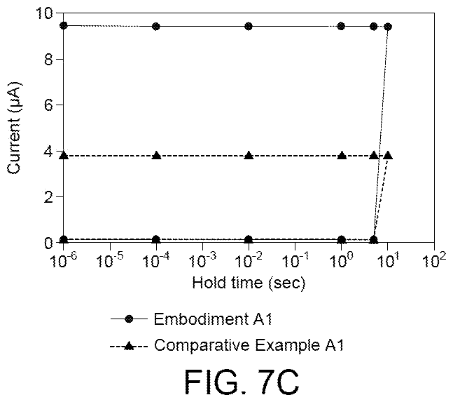

FIGS. 7A and 7B are diagrams showing time-bias waveform of the first gate structure 412, the second gate structure 414 and the bit line (BL) of one of the memory cell units according to the memory structure of Embodiment A1 in different operating states. The X-axis represents time (microsecond), and the Y-axis represents bias (V).

In FIG. 7A, one of the memory cell units of the memory structure 40 performs an erase operation. First, a logical value “0” is written (abbreviated as Write “0”), and then a hold operation (abbreviated as Hold) is performed. Thereafter, a read operation (abbreviated as Read) is performed.

In FIG. 7B, one of the memory cell units of the memory structure 40 performs a programming operation. First, a logical value “1” is written (abbreviated as Write “1”), and then a hold operation (abbreviated as Hold) is performed. Thereafter, a read operation (abbreviated as Read) is performed.

FIG. 7C is a diagram showing current-retention time relationship of Embodiment A1 and Comparative Example A1. The X-axis represents the hold time (second), and the Y-axis represents current (microampere) during the read operation (abbreviated as Read). The curves of Embodiment A1 and Comparative Example A1 both include curves corresponding to the low current state (corresponding to Write “0”) and curves corresponding to the high current state (corresponding to Write “1”). In the high current state (corresponding to Write “1”), the current of Embodiment A1 can reach about 9.4 microamps, and the current of Comparative Example A1 is about 3.7 microamps. It can be seen that the two-gate structure of Embodiment A1 can have a larger current than the three-gate structure of Comparative example A1. When the retention time is about 5 seconds, the currents of both Embodiment A1 and Comparative Example A1 rapidly increase from the low current state (corresponding to Write “0”) to the high current state (corresponding to Write “1”), which indicates that the two-gate structure of Embodiment A1 can have the retention time comparable to the retention time of the three-gate structure of Comparative Example A1, and the retention capability is not inferior.

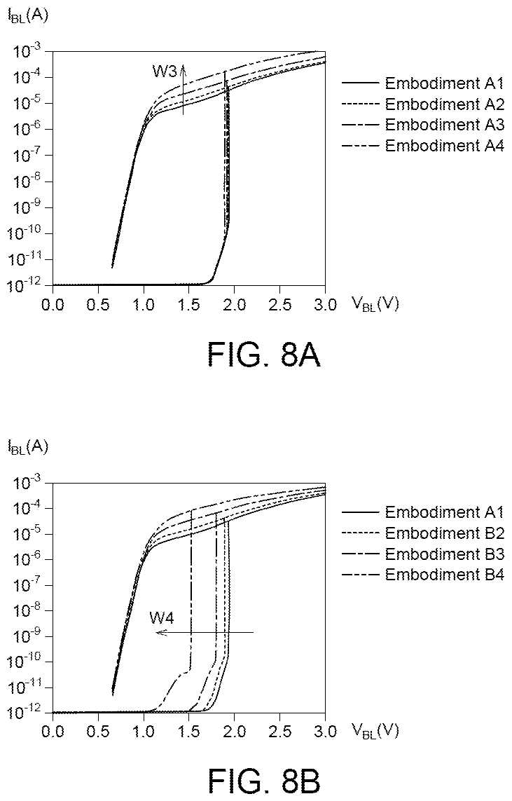

FIG. 8A is a diagram showing bit line current (IBL)-bit line voltage (VBL) (V) relationship curves of the memory cell units of Embodiments A1 to A4. Embodiment A1 is the memory structure 40 as shown in FIGS. 4A to 4B, in which the length of the first gate structure 412 in the first direction D1 is, for example, 90 nm. The lengths of the second gate structures of Embodiments A2 to A4 in the first direction D1 are the same as the lengths of the second gate structures 414 of Embodiment A1 in the first direction D1, for example, all are 90 nm. The difference between Embodiments A2 to A4 and Embodiment A1 is that the lengths of the first gate structures in the first direction D1 are different (other identical parts will not be repeatedly described), for example, the length of the first gate structure of Embodiment A2 in the first direction D1 is 70 nm; the length of the first gate structure of Embodiment A3 in the first direction D1 is 50 nm; the length of the first gate structure of Embodiment A4 in the first direction D1 is 30 nm. −1.5V is applied to the first gate structures of all Embodiments A1 to A4, and 1.5V is applied to the second gate structures of all Embodiments A1 to A4.

As shown in FIG. 8A, the break down voltages of Embodiments A1 to A4 have almost no change. In the curve of the high current state (corresponding to Write “1”), the on-current of Embodiment A4 is greater than the on-current of Embodiment A3, and the on-current of Embodiment A3 is greater than the on-current of Embodiment A2. The on-current of Embodiment A2 is greater than the on-current of Embodiment A1. It can be seen from this that as the length of the first gate structure in the first direction D1 becomes smaller, the on-current can become higher and higher, as shown by the arrow W3, and the window for read current can also increase.

FIG. 8B is a diagram showing bit line current-bit line voltage relationship curves of the memory cell units of Embodiments A1 and B2 to B4. Embodiment A1 is the memory structure 40 as shown in FIGS. 4A-4B, in which the length of the second gate structure 414 in the first direction D1 is, for example, 90 nm. The lengths of the first gate structures of Embodiments B2 to B4 in the first direction D1 are the same as the length of the first gate structure 412 of Embodiment A1 in the first direction D1, for example, all are 90 nm. The difference between Embodiments B2 to B4 and Embodiment A1 is that the lengths of the second gate structures in the first direction D1 are different (other identical parts will not be described again). For example, the length of the second gate structure of Embodiment B2 in the first direction D1 is 70 nm; the length of the second gate structure of Embodiment B3 in the first direction D1 is 50 nm; the length of the second gate structure of Embodiment B4 in the first direction D1 is 30 nm. −1.5V is applied to all of the first gate structures of Embodiments A1 and B2 to B4, and 1.5V is applied to all of the second gate structures all of Embodiments A1 and B2 to B4.

As shown in FIG. 8B, the break-down voltages of Embodiments B2 to B4 change, as shown by arrow W4. The break-down voltages of Embodiments B2 to B4 are all lower than the break-down voltage of Embodiment A1. For example, the break-down voltage of Embodiment B4 is lower than the break-down voltage of Embodiment B3, the break-down voltage of Embodiment B3 is lower than the break-down voltage of Embodiment B2, and the break-down voltage of Embodiment B2 is lower than the break-down voltage of Embodiment A1. It can be seen that as the length of the second gate structure in the first direction D1 becomes smaller, the break-down voltage becomes lower and lower. Since the memory cell units are operated by applying a bias to the bit line (BL), the bit line, which is the source of holes, triggers positive feedback, the break-down voltage depends on the potential barrier of the second gate structure that is closer to the bit line (BL), but not depends on the potential barrier of the first gate structure which is further away from the bit line. Therefore, changes in the length of the second gate structure in the first direction will affect the break-down voltage. For example, when the length of the second gate structure is shortened in the first direction, the potential barrier of the holes will decrease, so the break-down voltage will drop significantly; the change in the length of the first gate structure in the first direction has almost no impact on the break-down voltage. That is, reducing the length of the first gate structure in the first direction will increase the on-current, but will not affect the hysteresis loop.

In one embodiment, the size of the memory cell unit can be reduced by greatly shortening the length of the first gate structure in the first direction. Since the size of the first gate structure hardly affects the hysteresis loop, compared with the size of the second gate structure, the size of the first gate structure has a larger space for reduction.

In one embodiment, the break-down voltage can be reduced by reducing the length of the second gate structure in the first direction. In this way, the operating voltage can also be reduced, so the power consumption of operating the memory structure can be reduced.

Therefore, in the memory structure of the present invention, the size of the first gate structure and the second gate structure in the first direction can be adjusted according to actual needs. For example, when it is desired to reduce the memory size of the memory structure to a greater extent, the length of the first gate structure in the first direction can be selected to be greater than the length of the second gate structure in the first direction (as shown in FIG. 1B), or when it is desired to reduce the operating power consumption of the memory structure, you can choose to make the length of the second gate structure in the first direction greater than the length of the first gate structure in the first direction.

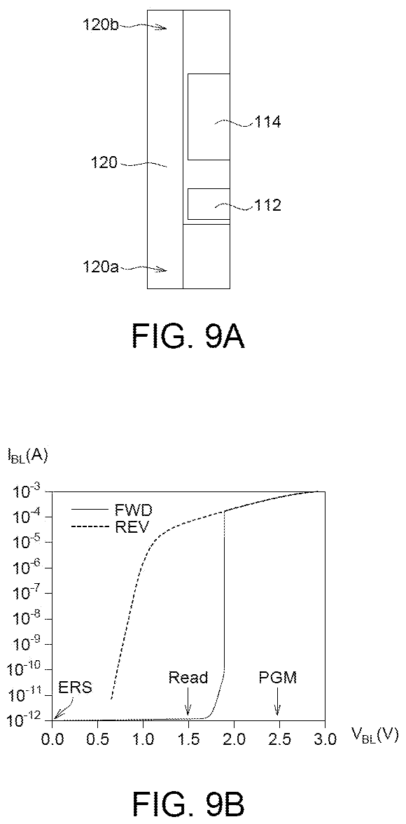

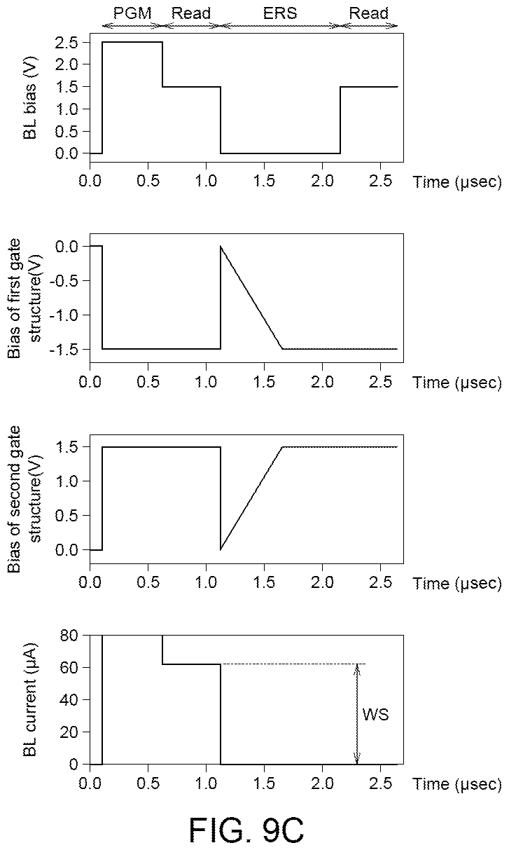

FIG. 9A shows a partial cross-sectional view of the memory structure of Embodiment A4. The length of the second gate structure in the first direction (for example, 90 nm) is greater than the length of the first gate structure in the first direction (e.g. 30 nm).

FIG. 9B is a schematic diagram showing bit line current-bit line voltage relationship curves of one of the memory cell units in the memory structure of Embodiment A4. FIG. 9C shows the changes in bias (volts) and current (microamperes) over time (microseconds) in different operating states of Embodiment A4. The erase operation is abbreviated as “ERS”, the read operation is abbreviated as “Read”, and the programming operation is abbreviated as “PGM”.

In FIG. 9B, the X-axis represents the bit line bias (VBL) in volts (V); the Y-axis represents the bit line current (IBL) in amperes (A); the solid curve represents forward bias FWD, the dashed curve represents reverse bias REV.

In FIG. 9C, the memory cell unit performs the operations of “PGM”, “Read”, “ERS” and “Read” in sequence. The bit line (BL) bias in the “PGM”, “Read”, “ERS” and “Read” states are 2.5V, 1.5V, 0V and 1.5V, respectively. The bias of the first gate structure 112 is −1.5V during “PGM” and “Read”. During “ERS”, the bias of the first gate structure 112 is pulled back to 0V for a while and then returns to −1.5V, and after “ERS”, it is still −1.5V at “Read”. The bias of the second gate structure 114 is 1.5V during “PGM” and “Read”. During “ERS”, the bias of the second gate structure 114 is pulled back to 0V for a while and then returns to 1.5V, and after “ERS”, it is still 1.5V at “Read”. It can be seen from the waveform diagram of the bit line (BL) current that it can have a current window of about 62 microamps, as shown in the interval of the double arrow WS.

By applying a suitable set of bias (for example, the bit line bias is 2.5V, 1.5V and 0V in the “PGM”, “Read” and “ERS” states respectively), the hysteresis loop in direct current (DC) as shown in FIG. 9B is formed, which can help produce proper operating results as shown in FIG. 9C.

FIG. 10 shows an equivalent circuit diagram of a memory structure according to an embodiment of the present invention (which may correspond to the embodiments as shown in FIGS. 1A-1B of the present invention or other embodiments).

Referring to FIGS. 1A and 10 at the same time. FIG. 10 exemplarily illustrates four adjacent channel bodies 220 in FIG. 1A. For example, each of intersection positions between the channel body 120 and the portion 1121 in the first gate structure 112 and the portion 1141 in the second gate structure 114 forms a transistor. As shown in FIG. 10, transistors TA1 and TA2 connected through the same channel body 120 together form a memory cell unit CA; transistors TB1 and TB2 connected through the same channel body 120 together form a memory cell unit CB; transistors TC1 and TC2 connected through the same channel body 120 together form a memory cell unit CC; transistors TD1 and TD2 connected through the same channel body 120 together form a memory cell unit CD. The first end 120a of the channel body 120 is connected to the corresponding first side pad CP. The first side pads CP in different layer is in electrical contact with the first side plug 140 and are electrically connected to the source line. Therefore, The memory cell units CA-CD are connected to the common source line CSL (that is, the same potential). The second end 120b of the channel body 220 is connected to the corresponding second side plug 150, that is, the channel bodies 120 that overlap each other in the third direction D3 are connected to the same second side plug 150, and the second side plugs 150 may serve as bit lines, for example, memory cell units CA and CC are electrically connected to the first bit line BL1, and memory cell units CB and CD are electrically connected to the second bit line BL2.

In the present embodiment, the memory cell unit CA is the memory cell unit to be selected, and the other memory cell units CB-CD are unselected memory cell units (for example, inhibited memory cell units). Different bias may be applied to the portion 1121 of the first gate structure 112, the portion 1122 of the first gate structure 112, the portion 1141 of the second gate structure 114, the portion 1142 of the second gate 114 structure, the first bit line BL1, the second bit line BL2 and the common source line CSL according to Tables 1 to 3 below, to perform different operation modes, for example, operating modes similar to those described in the relevant paragraphs of Tables 1 to 3 below, “Read disturb”, “PGM disturb”, “ERS disturb”, or other operating modes, (detailed below).

In one embodiment, the memory structure performs a read operation. Since the memory cell units AC and CC share the same first bit line BL1, in order to avoid a leakage current generated in unselected memory cell unit CC during operating the selected memory cell unit AC to be selected, a larger voltage (for example, |2.5|V) can be applied to the word lines (i.e., the portion 1122 of the first gate structure 112 and the portion 1142 of the second gate structure 114) connecting the memory cell unit CC to turn off the leakage current of the memory cell unit CC, and it is necessary to confirm the bit line current of the memory cell unit CC through simulation experiments (such as TCAD), as shown in FIG. 11. The above-mentioned operation of applying a larger voltage to the bit line connected to the memory cell unit CC represents an interruption state during the read operation (abbreviated as “Read”) (that is, the original state is restored after the interruption state), which can be called as read disturbance, abbreviated as “Read disturb”. The operating voltage in the “Read disturb” state can be referred to Table 1 as shown below.

TABLE 1

| | Read |
|---|---|
| Operating mode | disturb |
| Portion 1121 of first gate | −1.5 |
| structure 112 (V) | |
| Portion 1122 of first gate | −2.5 |
| structure 112 (V) | |
| Portion 1141 of second | 1.5 |
| gate structure 114 (V) | |
| Portion 1142 of second | 2.5 |
| gate structure 114 (V) | |
| First bit line BL1 (V) | 1.5 |
| Second bit line BL2 (V) | 0 |
| Common source line CSL | 0 |
| (V) | |

FIG. 11 shows the simulation results of the read operation of the memory cell unit CC; for example, it illustrates the changes with time (microseconds) in the bias (V) applied to the first bit line BL1, the bias (V) applied to the portion 1122 of the first gate structure 112, the bias (V) applied to the portion 1142 of the second gate structure 114 and the first bit line current (microampere) under the operating states “PGM”, “Read”, “Read disturb” and “Read”. Referring to Table 1 and FIG. 11 at the same time, 0V can be applied to the unselected second bit line BL2 to turn off the current from the memory cell unit CB and the memory cell unit CD. It can be seen from the simulation results in FIG. 11 that in the “Read disturb” state, the memory cell unit CC has no bit line current, as shown by arrow W5. It can be seen that the bit line current of the memory cell unit CC is completely turned off indeed by increasing the voltage of word lines (i.e. gate structures) of the memory cell unit CC (for example, increasing from |1.5|V to |2.5|V). In addition, the read current of the memory cell unit CC in the “Read” state before the “Read disturb” state and in the “Read” state after the “Read disturb” state does not change (as shown by arrow WT), which indicates that the memory cell unit CC is maintained in a good state and has not been affected by “Read disturb”.

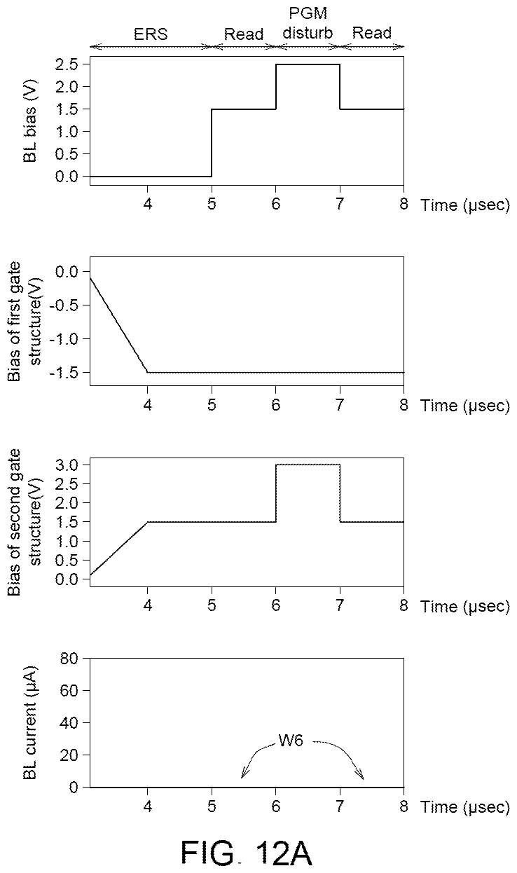

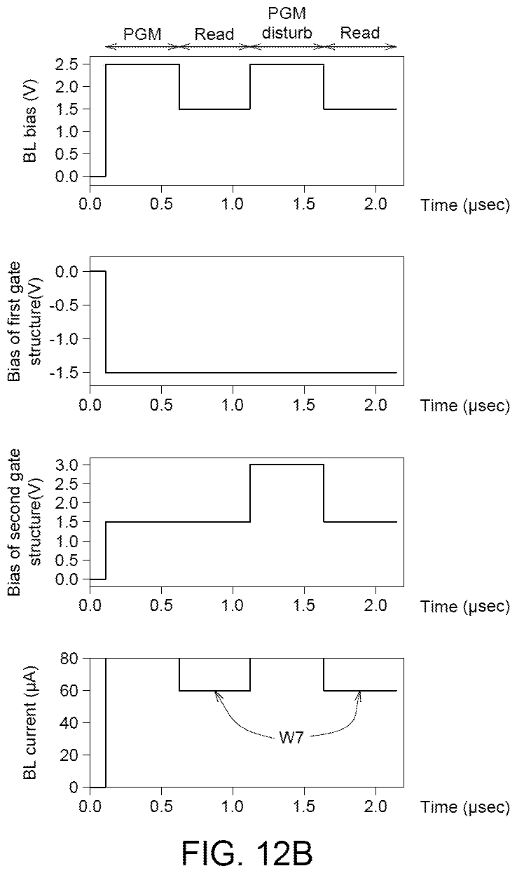

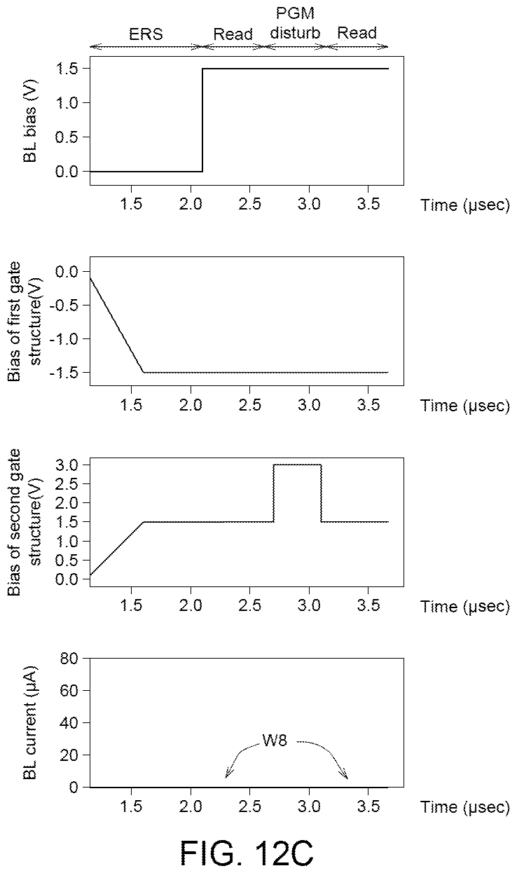

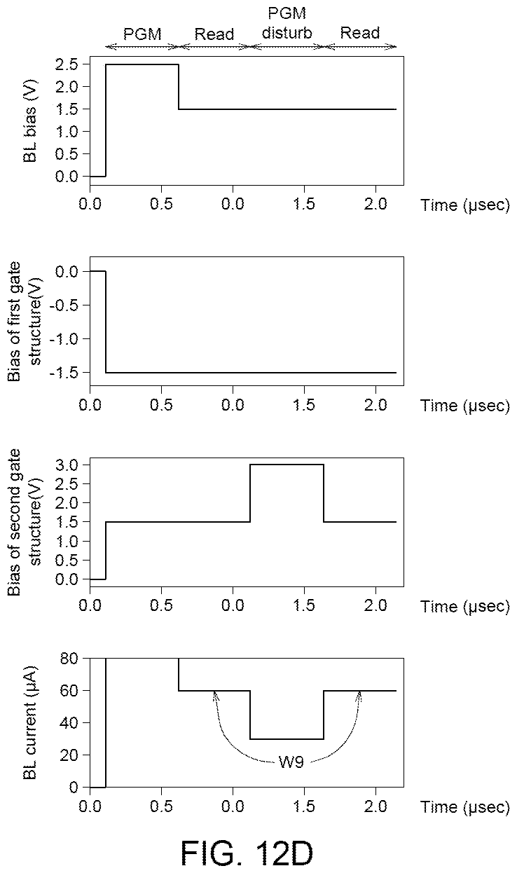

In one embodiment, the memory structure performs a programming operation, that is, from “0” state to “1” state. When the memory cell unit CA is selected for the programming operation, in order to prevent the unselected memory cell units CC and CD from being programmed, a larger voltage (for example, 3V) is applied to the portion 1142 of the second gate structure 114 to increase the potential barrier of PNPN so that programming can be inhibited, and it is necessary to confirm the bit line current of memory cell units CC and CD through simulation experiments, as shown in FIGS. 12A-12D. The above-mentioned operation of applying a larger voltage (for example, 3V) to the portion 1142 of the second gate structure 114 represents an interruption state during the programming operation (referred to as “PGM”) (that is, the original state is restored after the interruption state), which can be called as programming disturbance, abbreviated as “PGM disturb”. The operating voltages in the “PGM disturb” state can be referred to Table 2 as shown below.

TABLE 2

| | PGM |
|---|---|
| Operating mode | disturb |
| Portion 1121 of first gate | −1.5 |
| structure 112 (V) | |
| Portion 1122 of first gate | −1.5 |
| structure 112 (V) | |
| Portion 1141 of second | 1.5 |
| gate structure 114 (V) | |
| Portion 1142 of second | 3 |
| gate structure 114 (V) | |
| First bit line BL1 (V) | 2.5 |
| Second bit line BL2 V) | 1.5 |
| Common source line CSL | 0 |
| (V) | |

FIG. 12A shows the simulation results of the programming operation of the memory cell unit CC at the “0” state; for example, it illustrates the changes with time (microseconds) in the bias (V) applied to the first bit line BL1, the bias (V) applied to the portion 1122 of the first gate structure 112, the bias (V) applied to the portion 1142 of the second gate structure 114 and the first bit line current (microampere) under the operating states “ERS”, “Read”, “PGM disturb” and “Read”. Referring to FIG. 12A, the first bit line currents in the “Read” state before the “PGM disturb” state and in the “Read” state after the “PGM disturb” are the same, as shown by arrow W6.

FIG. 12B shows the simulation results of the programming operation of the memory cell unit CC at the “1” state; for example, it illustrates the changes with time (microseconds) in the bias (V) applied to the first bit line BL1, the bias (V) applied to the portion 1122 of the first gate structure 112, the bias (V) applied to the portion 1142 of the second gate structure 114 and the first bit line current (microampere) under the operating states “PGM”, “Read”, “PGM disturb” and “Read”. Referring to FIG. 12B, the first bit line currents in the “Read” state before the “PGM disturb” state and in the “Read” state after the “PGM disturb” are the same, as shown by arrow W7.

FIG. 12C shows the simulation results of the programming operation of the memory cell unit CD at the “0” state; for example, it illustrates the changes with time (microseconds) in the bias (V) applied to the second bit line BL2, the bias (V) applied to the portion 1122 of the first gate structure 112, the bias (V) applied to the portion 1142 of the second gate structure 114 and the second bit line current (microampere) under the operating states “ERS”, “Read”, “PGM disturb” and “Read”. Referring to FIG. 12C, the second bit line currents in the “Read” state before the “PGM disturb” state and in the “Read” state after the “PGM disturb” are the same, as shown by arrow W8.

FIG. 12D shows the simulation results of the programming operation of the memory cell unit CD at the “1” state; for example, it illustrates the changes with time (microseconds) in the bias (V) applied to the second bit line BL2, the bias (V) applied to the portion 1122 of the first gate structure 112, the bias (V) applied to the portion 1142 of the second gate structure 114 and the second bit line current (microampere) under the operating states “PGM”, “Read”, “PGM disturb” and “Read”. Referring to FIG. 12D, the second bit line currents in the “Read” state before the “PGM disturb” state and in the “Read” state after the “PGM disturb” are the same, as shown by arrow W9.

It can be seen from the simulation results of FIGS. 12A to 12D that the programming of memory cell units CC and CD are successfully inhibited at both the “0” state and the “1” state by increasing the voltage applied to the portion 1142 of the unselected second gate structure 114 to 3V.

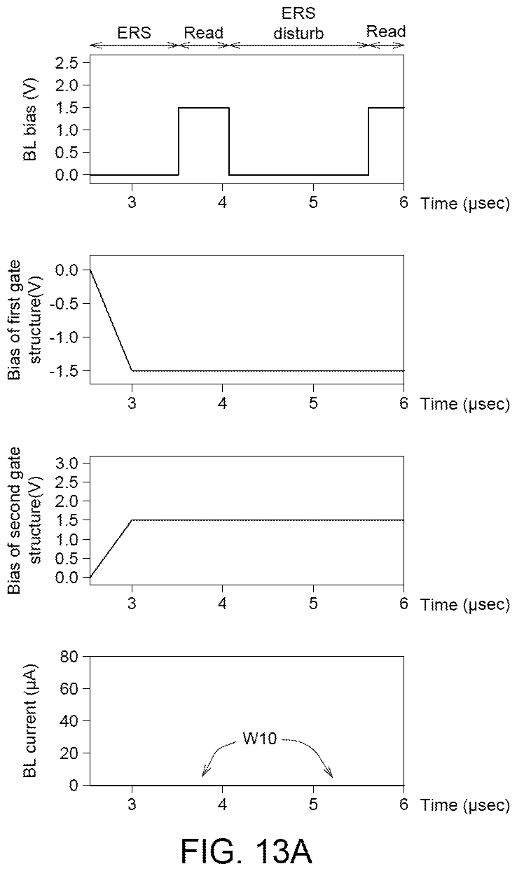

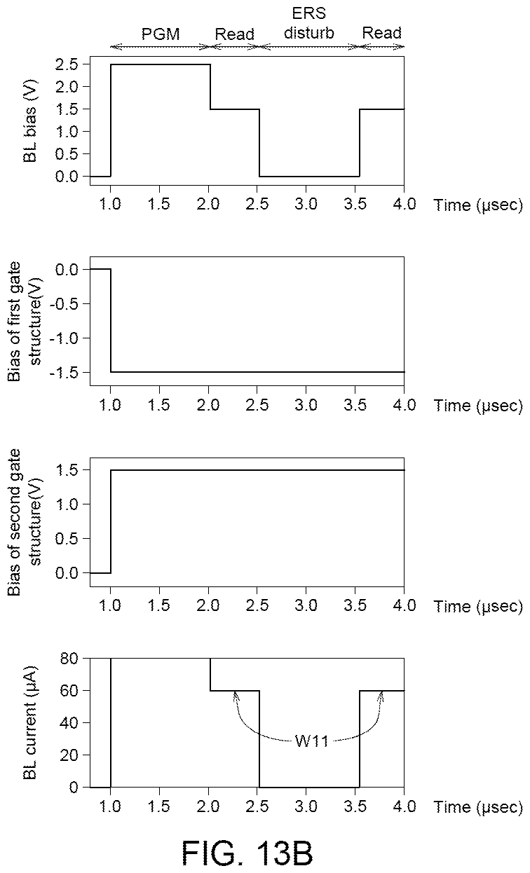

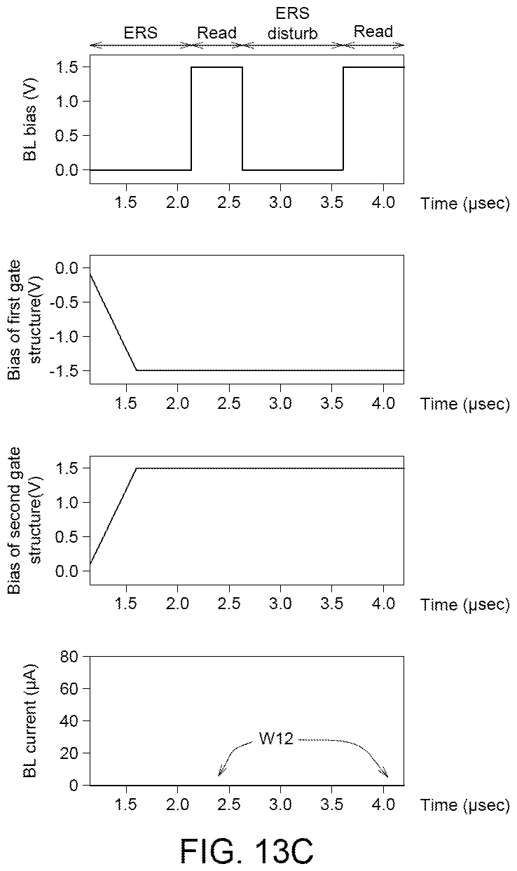

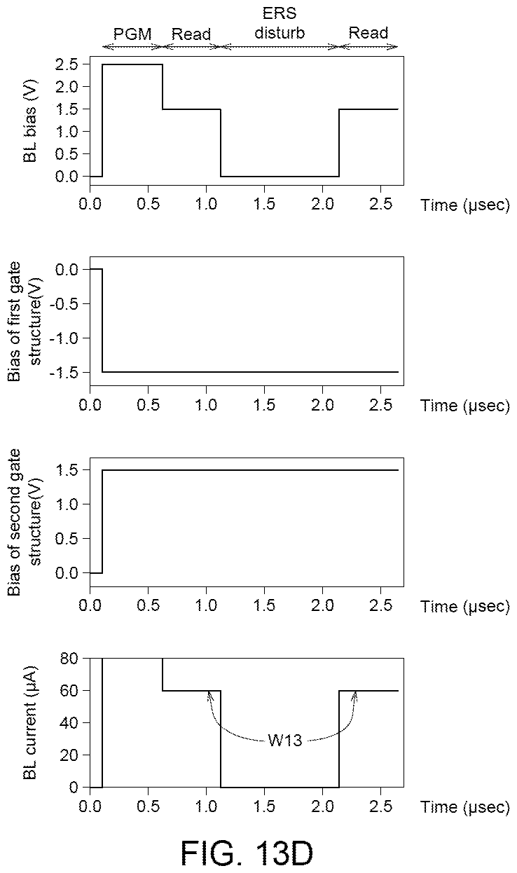

In one embodiment, the memory structure performs an erase operation, that is, from “1” state to “0” state. When the memory cell unit CA is selected to perform an erase operation, a word line bias reset-up step is performed on the gate structures connected to the memory cell unit CA (such as, the portion 1121 of the first gate structure 112 and the portion 1141 of the second gate structure 114), and the memory cell units CA and CB are simultaneously erased in page manner. In order to prevent the unselected memory cell units CC and CD from being erased, the word line bias reset-up step is not performed to the gate structures connected to the memory cell units CC and CD (for example, the portion 1122 of the first gate structure 112 and the portion 1142 of the second gate structure 114), and it is necessary to confirm the bit line currents of the memory cell units CC and CD through simulation experiments, as shown in FIGS. 13A to 13D. The word line bias reset-up step is, for example, implemented by temporarily pulling the operating voltage back to 0V, such as sequentially applying operating voltages of −1.5V, 0V and −1.5V to the portion 1121 of the first gate structure 112, and operating voltages of 1.5V, 0V and 1.5V are sequentially applied to the portion 1141 of the second gate structure 114. The above operation of not performing the word line bias reset-up step on the gate structures connected to the memory cell units CC and CD (such as the portion 1122 of the first gate structure 112 and the portion 1142 of the second gate structure 114) represents an interruption state during the erase operation (abbreviated as “ERS”) (i.e., the original state is restored after the interruption state), which can be called as an erase disturbance, abbreviated as “ERS disturb”. The operating voltages in the “ERS disturb” state can be referred to Table 3 as shown below.

TABLE 3

| Operating mode | ERS disturb |
|---|---|
| Portion 1121 of first gate | −1.5→0→1.5 |
| structure 112 (V) | |
| Portion 1122 of first gate | −1.5 |
| structur e112 (V) | |
| Portion 1141 of second | 1.5→0→1.5 |
| gate structure 114 (V) | |
| Portion 1142 of second | 1.5 |
| gate structure 114 (V) | |
| First bit line BL1 (V) | 0 |
| Second bit line BL2 (V) | 0 |
| Common source line CSL | 0 |
| (V) | |

FIG. 13A shows the simulation results of the erase operation of the memory cell unit CC at the “0” state; for example, it illustrates the changes with time (microseconds) in the bias (V) applied to the first bit line BL1, the bias (V) applied to the portion 1122 of the first gate structure 112, the bias (V) applied to the portion 1142 of the second gate structure 114 and the first bit line current (microampere) under the operating states “ERS”, “Read”, “ERS disturb” and “Read”. Referring to FIG. 13A, the first bit line currents at the “Read” state before the “ERS disturb” state and at the “Read” state after the “ERS disturb” are the same, as shown by arrow W10.

FIG. 13B shows the simulation results of the erase operation of the memory cell unit CC at the “1” state; for example, it illustrates the changes with time (microseconds) in the bias (V) applied to the first bit line BL1, the bias (V) applied to the portion 1122 of the first gate structure 112, the bias (V) applied to the portion 1142 of the second gate structure 114 and the first bit line current (microampere) under the operating states “PGM”, “Read”, “ERS disturb” and “Read”. Referring to FIG. 13B, the first bit line currents at the “Read” state before the “ERS disturb” state and at the “Read” state after the “ERS disturb” are the same, as shown by arrow W11.

FIG. 13C shows the simulation results of the erase operation of the memory cell unit CD at the “0” state; for example, it illustrates the changes with time (microseconds) in the bias (V) applied to the second bit line BL2, the bias (V) applied to the portion 1122 of the first gate structure 112, the bias (V) applied to the portion 1142 of the second gate structure 114 and the second bit line current (microampere) under the operating states “ERS”, “Read”, “ERS disturb” and “Read”. Referring to FIG. 13C, the second bit line currents at the “Read” state before the “ERS disturb” state and at the “Read” state after the “ERS disturb” are the same, as shown by arrow W12.

FIG. 13D shows the simulation results of the erase operation of the memory cell unit CD at the “1” state; for example, it illustrates the changes with time (microseconds) in the bias (V) applied to the second bit line BL2, the bias (V) applied to the portion 1122 of the first gate structure 112, the bias (V) applied to the portion 1142 of the second gate structure 114 and the second bit line current (microampere) under the operating states “PGM”, “Read”, “ERS disturb” and “Read”. Referring to FIG. 13D, the second bit line currents at the “Read” state before the “ERS disturb” state and at the “Read” state after the “ERS disturb” are the same, as shown by arrow W13.

It can be seen from the simulation results of FIGS. 13A to 13D that the erase of both of memory cell units CC and CD are successfully inhibited whether at the “0” state or the “1” state by not performing the word line bias reset-up step on the gate structures connected to the memory cell units CC and CD (such as the portion 1122 of the first gate structure 112 and the portion 1142 of the second gate structure 114).

It can be seen from the simulation results in FIGS. 11 to 13D that the memory structure according to an embodiment of the present invention is feasible regardless of the “Read”, “PGM” or “ERS” operations.

According to an embodiment, a memory structure includes a substrate having an upper surface; a first gate structure and a second gate structure disposed on the substrate, separated from each other in a first direction and extend in a second direction, respectively; and a plurality of channel bodies separated from each other in the first direction and a third direction, and penetrating the first gate structure and the second structure, respectively. The first direction, the second direction and the third direction intersect each other. The upper surface is parallel to the first direction and the second direction, and a normal direction of the upper surface is parallel to the third direction. A first length of the first gate structure in the first direction and a second length of the second gate structure in the first direction are different from each other. Compared with the comparative example in which the first length of the first gate structure in the first direction and the second length of the second gate structure in the first direction are the same as each other, the first gate structure or the second gate structure of the present invention can have a smaller length in the first direction, so that the first gate structure or the second gate structure can occupy a smaller volume, so the size of the memory structure can be reduced, in line with the requirements for miniaturization. On the other hand, the memory structure of the present invention can also have a smaller operating voltage, so the power consumption of operating the memory structure can be reduced. Furthermore, the memory structure of the present invention is a memory structure based on the operation mechanism of thyristor, and still has the advantages of high scalability and fast operating speed.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory structure, comprising:
a substrate, having an upper surface;
a first gate structure and a second gate structure, disposed on the substrate, separated from each other in a first direction and extending in a second direction, respectively; and
a plurality of channel bodies separated from each other in the first direction and a third direction, and penetrating the first gate structure and the second structure, respectively,
wherein the first direction, the second direction and the third direction intersect each other, the upper surface is parallel to the first direction and the second direction, and a normal direction of the upper surface is parallel to the third direction,
wherein a first length of the first gate structure in the first direction and a second length of the second gate structure in the first direction are different from each other.

2. The memory structure according to claim 1, further comprising:
a plurality of pads, stacked along the third direction and separated from each other along the third direction, each of the pads connecting a first end of a corresponding one of the channel bodies;
a first side plug, extending along the third direction and connecting the pads; and
a plurality of second side plugs, respectively extending along the third direction and separated from each other in the second direction, each of the second side plugs connecting a second end of a corresponding one of the channel bodies, wherein the second end is opposite to the first end, wherein the first gate structure is closer to the first end than the second gate structure.

3. The memory structure according to claim 2, wherein the first length is smaller than the second end.

4. The memory structure according to claim 2, wherein the second length is smaller than the first end.

5. The memory structure according to claim 2, wherein the first gate structure comprises a plurality of portions, the second gate structures comprises a plurality of portions, the portions of the first gate structure respectively extend along the second direction and are separated from each other along the third direction, the portions of the second gate structure respectively extend along the second direction and are separated from each other along the third direction.

6. The memory structure according to claim 5, wherein lengths of the portions of the first gate structure in the second direction are different from each other, and lengths of the portions of the second gate structure in the second direction are different from each other.

7. The memory structure according to claim 5, further comprising:
a plurality of first contacts, separated from each other along the second direction and respectively extending along the third direction to electrically contact the a plurality of first landing regions on the portions of the first gate structure, wherein the first landing regions form a staircase structure; and
a plurality of second contacts, separated from each other along the second direction and respectively extending along the third direction to electrically contact the a plurality of second landing regions on the portions of the second gate structure, wherein the second landing regions form another staircase structure.

8. The memory structure according to claim 2, wherein the first gate structure is a continuous structure in the third direction, and the second gate structure comprises a plurality of portions respectively extending along the second direction and separated from each other along the third direction.

9. The memory structure according to claim 8, wherein the first gate structure corresponds to all of the channel bodies, and the portions of the second gate structure respectively correspond to a portion of the channel

10. The memory structure according to claim 8, further comprising a plurality of contacts separated from each other along the second direction, and respectively extending along the third direction to electrically contact a plurality of landing regions on the portions of the second gate structure, wherein the landing regions form a staircase structure.

11. The memory structure according to claim 2, wherein the first gate structure comprises a plurality of portions respectively extending along the second direction and separated from each other along the third direction, and the second gate structure is a continuous structure in the third direction.

12. The memory structure according to claim 11, wherein the portions of the first gate structure respectively correspond to a portion of the channel bodies, and the second gate structure corresponds to all of the channel bodies.

13. The memory structure according to claim 12, further comprising a plurality of contacts separated from each other along the second direction, and respectively extending along the third direction to electrically contact a plurality of landing regions on the portions of the first gate structure, wherein the landing regions form a staircase structure.

14. The memory structure according to claim 1, further comprising a plurality of dielectric films disposed between the first gate structure and the channel bodies and between the second gate structure and the channel

15. The memory structure according to claim 2, wherein the first end comprises a first conductivity type dopant, the second end comprises a second conductivity type dopant, and the second conductivity type dopant is different from the first conductivity type dopant.

16. The memory structure according to claim 2, wherein the first side plug serves as a common source line.

17. The memory structure according to claim 2, wherein each of the second side plugs serves as a bit line.

18. The memory structure according to claim 1, wherein the first gate structure and the second gate structure serve as one or more word lines respectively.

19. The memory structure according to claim 1, further comprising a plurality of memory cell units, each of the memory cell units are formed by a corresponding one of the channel bodies, the first gate structure and the second gate structure.

20. The memory structure according to claim 1, wherein an operating mechanism of the memory structure is based on a thyristor.
